(19) United States
(12) Patent Application Publication
(10) Pub. No.: US 2007/0170536 A1
(43) Pub. Date: Jul. 26, 2007

(54) Liquid phase epitaxial GOI photodiode with buried high resistivity germanium layer

(75) Inventors: Sheng Teng Hsu, Camas, WA (US); Jong-Jan Lee, Camas, WA (US); Jer-Shen Maa, Vancouver, WA (US); Douglas J. Tweet, Camas, WA (US)

Correspondence Address: SHARP LABORATORIES OF AMERICA, INC.;C/O LAW OFFICE OF GERALD MALISZEWSKI, P.O. BOX 270829, SAN DIEGO, CA, 92198-2829, US

(73) Assignee: Sharp Laboratories of America, Inc.

(21) Appl. No.: 11/339,011

(22) Filed: Jan. 25, 2006

(51) Int. Cl. H01L 31/00

(52) U.S. Cl. 257/458

(57) ABSTRACT

A device and associated method are provided for fabricating a liquid phase epitaxial (LPE) Germanium-on-Insulator (GOI) photodiode with buried high resistivity Germanium (Ge) layer. The method provides a silicon (Si) substrate, and forms a bottom insulator overlying the Si substrate with a Si seed access area. Then, a Ge P-I-N diode is formed with an n +-doped (n+) mesa, a p+-doped (p+) Ge bottom insulator interface and mesa lateral interface, and a high resistivity Ge layer interposed between the p+ Ge and n+ Ge. A metal electrode is formed overlying a region of the p+ Ge lateral interface, and a transparent electrode is formed overlying the n+ Ge mesa. In one aspect, the method deposits a silicon nitride layer temporary cap overlying the high resistivity Ge layer, and an annealing is performed to epitaxially crystallize the Ge bottom interface and high resistivity Ge layer.

### BACKGROUND OF THE INVENTION

1. Field of the Invention

This invention generally relates to integrated circuit (IC) fabrication and, more particularly, a liquid phase epitaxial (LPE) Germanium-on-Insulator (GOI) photodiode with a buried high resistivity Germanium (Ge) layer.

2. Description of the Related Art

A photodiode is a p-n junction receptive to optical input. Photodiodes can be either zero biased or reverse biased. If zero biased, light creates a current in the forward bias direction. This phenomena is called the photovoltaic effect. If reverse biased, photodiodes have a high resistance that is reduced when light is introduced to the p-n junction. A reverse biased diode is typically more sensitive to light, and can be used as a detector if the current flow is monitored. Phototransistors rely upon the p-n junction to detect light, but are typically more sensitve to light than a diode.

There are many applications for photodetection in the near infrared region (the wavelength between 0.7 micron to 2 microns), such as in fiber-optical communication, security, and thermal imaging. Although III-V compound semiconductors provide superior optical performance over their silicon (Si)-based counterparts, the use of Si is desirable, as the compatibility of Si-based materials with conventional Si-IC technology promises the possibility of cheap, small, and highly integrated optical systems. Silicon photodiodes are widely used as photodetectors in the visible light wavelengths due to their low dark current and the above-mentioned compatibility with Si IC technologies.

Ge is a material with potential use in the fabrication of photo devices. Ge has a higher carrier mobility than Si, and is receptive to a different spectrum of light than Si. The first paper addressing high-speed photodetectors fabricated on Ge-on-Insulator substrates was presented at the 2004 IEDM by Liu et al. [Yaocheng Liu, Kailash Gopalakrishnan, Peter B. Griffin, Kai Ma, Michael D. Deal, and James D. Plummer, “MOSFETs and High-Speed Photodetectors on Ge-on Insulator Substrates” 2004 IEDM Technical Digest, pg. 1001-1004]. However, the reported photodiode had a large dark current, and therefore, is not suitable for high-density large-scale commercial applications. The leakage current is attributed to the poor Ge crystallinity at the Ge to insulator interface.

### SUMMARY OF THE INVENTION

The present invention provides a GOI structure to overcome the large dark current problem associated with poor Ge crystallinity at a Ge-to-insulator interface. The structure is a vertical P-I-N diode with p+-doped Ge-buried insulator interface. The perimeter of the diode is also doped p+. This structure eliminates Ge-buried insulator and lateral interface leakage current.

Accordingly, a method is provided for fabricating a liquid phase epitaxial (LPE) Germanium-on-Insulator (GOI) photodiode with buried high resistivity Ge layer. The method provides a silicon (Si) substrate, and forms a bottom insulator overlying the Si substrate with a Si seed access area. Then, a Ge P-I-N diode is formed with an n +-doped (n+) mesa, a p+-doped (p+) Ge bottom insulator interface and mesa lateral interface, and a high resistivity Ge layer interposed between the p+ Ge and n+ Ge. A metal electrode is formed overlying a region of the p+ Ge lateral interface, and a transparent electrode is formed overlying the n+ Ge mesa.

In one aspect, the method deposits a silicon nitride layer temporary cap overlying the high resistivity Ge layer, anneals the Ge bottom interface and high resistivity Ge layer, and from the Si seed access area, epitaxially crystallizes the Ge bottom interface and high resistivity Ge layer.

The p+ Ge bottom insulator interface is formed by depositing a Ge layer overlying the bottom insulator and Si seed access area, and implanting a p+ dopant into the Ge layer. The high resistivity Ge layer is formed by depositing another layer of Ge, overlying the p+-doped Ge layer. The p+ Ge mesa lateral interface is formed by selectively p+-doping the perimeter of the high resistivity Ge layer.

Additional details of the above-described method, and a LPE GOI photodiode with a buried high resistivity Ge layer are provided below.

### BRIEF DESCRIPTION OF THE DRAWINGS

FIG. 1 is a partial cross-sectional view of a liquid phase epitaxial (LPE) Germanium-on-Insulator (GOI) photodiode with a buried high resistivity Germanium (Ge) layer.

FIG. 2 is a partial cross-sectional view, showing a variation of the LPE GOI photodiode of FIG. 1.

FIGS. 3 through 8 are partial cross-sectional views depicting steps in the fabrication of the present invention P-I-N photodiode.

FIG. 9 is a flowchart illustrating a method for fabricating a LPE GOI photodiode with buried high resistivity Ge layer.

FIG. 10 is a flowchart depicting a variation in the fabrication method of FIG. 9.

### DETAILED DESCRIPTION

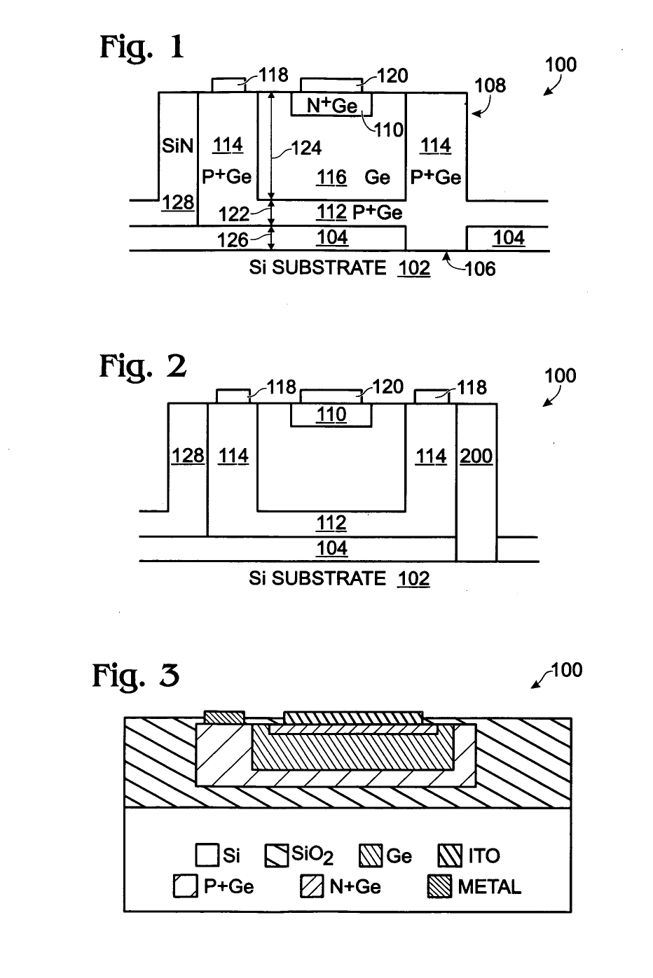

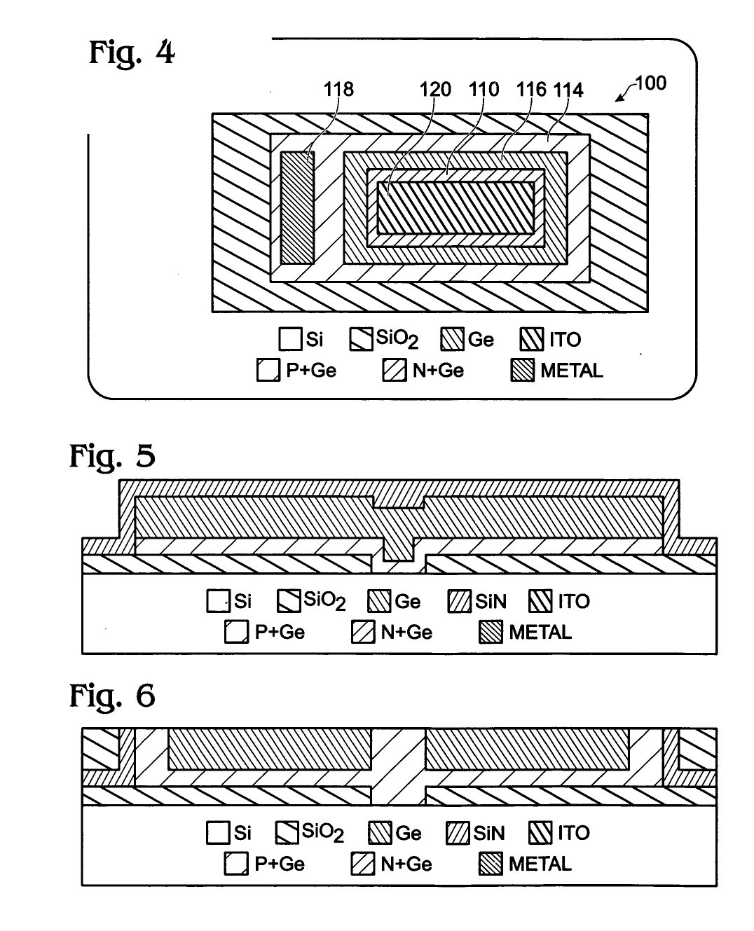

FIG. 1 is a partial cross-sectional view of a liquid phase epitaxial (LPE) Germanium-on-Insulator (GOI) photodiode with a buried high resistivity Germanium (Ge) layer. The photodiode 100 comprises a silicon (Si) substrate 102 and a bottom insulator 104 overlying the Si substrate 102 with a Si seed access area 106. Also shown is Ge P-I-N diode 108. The P-I-N diode 108 has an n+-doped (n+) mesa 110, a p+-doped (p+) Ge bottom insulator interface 112 and mesa lateral interface 114, and a high resistivity Ge layer 116 interposed between the p+ Ge 112/114 and n+ Ge 110. As seen more clearly in FIG. 4, the p+ Ge mesa lateral interface 114 forms a perimeter around the high resistivity Ge layer 116. A metal electrode 118 overlies a region of the p+ Ge mesa lateral interface 114. A transparent electrode 120 overlies the n+ Ge mesa 110. For example, the transparent electrode can be a conductive material such as ITO or a thin layer of Au.

In one aspect, the p+ Ge bottom insulator interface 112 has a thickness 122 in the range of about 20 to 50 nanometers (nm). The high resistivity Ge layer 116 has a thickness 124 in the range of about 0.3 and 3 micrometers (um). Typically, the bottom insulator 104 is silicon oxide, although other insulator materials are widely known in the art, and has a thickness 126 in the range of about 10 to 40 nm.

Also shown is a silicon nitride insulator 128 overlying the bottom insulator 104 and adjacent the p+ Ge mesa lateral interface 114. Again, other material besides silicon nitride may be used to form insulator 128.

FIG. 2 is a partial cross-sectional view, showing a variation of the LPE GOI photodiode of FIG. 1. As shown, the silicon nitride insulator 128 forms a wall 200 overlying the Si seed access area 106. The metal electrode 118 overlies a region of p+ Ge mesa lateral interface 114 adjacent the silicon nitride wall 200.

### Functional Description

FIGS. 3 through 8 are partial cross-sectional views depicting steps in the fabrication of the present invention P-I-N photodiode. FIG. 3 is a simplified view of the device of FIG. 1. FIG. 4 is a plan view showing that the Ge-buried insulator interface and Ge mesa lateral interface are all doped p+. It is the p+ layer that eliminates all dark current from the back and the side interfaces.

The fabrication process is as follows:

1. Complete the fabrication of silicon CMOS circuits using any state-of-the-art process. Deposit a thick layer of oxide on the substrate. Chemical-mechanical polish (CMP) planarize the silicon oxide.

2. Photoresist. Etch the silicon oxide to open the silicon seed areas.

3. Deposit 20 nm to 50 nm of polycrystalline or amorphous Ge.

4. Implant Indium ions. The energy is 30 KeV to 50 KeV. The dose is 2×10¹³ to 1×10¹⁵ /cm².

5. Deposit a second layer of 0.3 μm to 3 μm of polycrystalline or amorphous Ge.

6. Photoresist mask and etch the Ge. Deposit 20 nm to 100 nm of silicon nitride as is shown in FIG. 5, which is a cross-sectional view after the polycrystalline Ge is etched and nitride passivation performed.

Rapid thermal anneal (RTA) at about 930° C. to 1000° C. for 0 to 5 seconds. A zero second duration means the once the RTA temperature reaches the target temperature, the device is immediately permitted to cool down. During this anneal, the Ge film melts, and the SiN and SiO₂ films act as a microcrucible, holding the Ge liquid from flowing randomly. The Si substrate, SiO₂ and SiN remain solid. The wafer is then cooled. During cooling, LPE occurs, as the growth front moves from the Si/Ge interface in the seeding windows, and propagates laterally sweeping across the entire Ge deposition. In this way single crystalline Ge is formed with defects concentrated and terminated only at the seeding window and Ge insulator interface.

7. Deposit silicon oxide having thickness about 1.5 times that of the thickness of Ge and silicon nitride. CMP, stopping at the nitride. Etch the silicon nitride.

8. Photoresist. Perform multiple boron ion implantations to dope the perimeters of Ge island to p+. See FIG. 6, which is a cross-sectional view after p+ ion implantation.

9. Photoresist mask and perform an Arsenic n+ ion implantation. The energy is 10 KeV to 50 KeV. The ion dose is 2×10¹³ to 1×10¹⁵/cm².

10. Deposit a thin layer silicon oxide of about 10 nm to 40 nm.

11. Photoresist mask and etch contact holes.

12. Deposit a transparent metal such as indium tin oxide (ITO). Note, there are many other transparent conductor materials known in the art that may be used as an alternative to ITO.

13. Photoresist mask and etch the transparent metal.

14. Photoresist mask and etch contact holes to the CMOS circuit.

15. Deposit an interconnect metal such as Al. The Al contact to the transparent metal is preferably outside of the active P-I-N diode region.

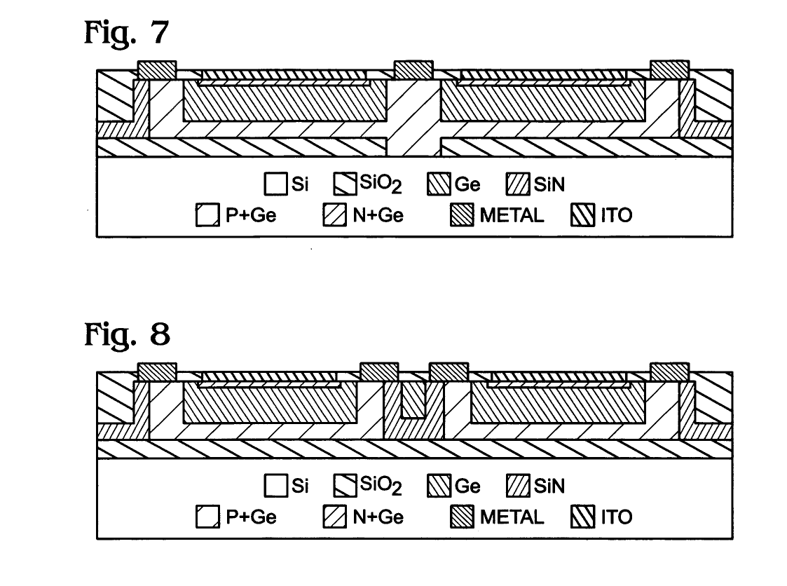

16. Photoresist mask and etch the interconnection metal, see FIG. 7, which is a cross-sectional view after the metallization.

FIG. 8 is a variation of the device of FIG. 2, depicting a cross-sectional view of two P-I-N diodes isolated from a silicon substrate. The Al contact for the p+ Ge is connected to silicon at the seed area. In some aspects it may be useful to have the P-I-N diode completely isolated from the silicon substrate. If it is so desired, an additional step is added after Step 7 to etch off the Ge in the seed area. Then, the rest of the above-mentioned fabrication steps are followed.

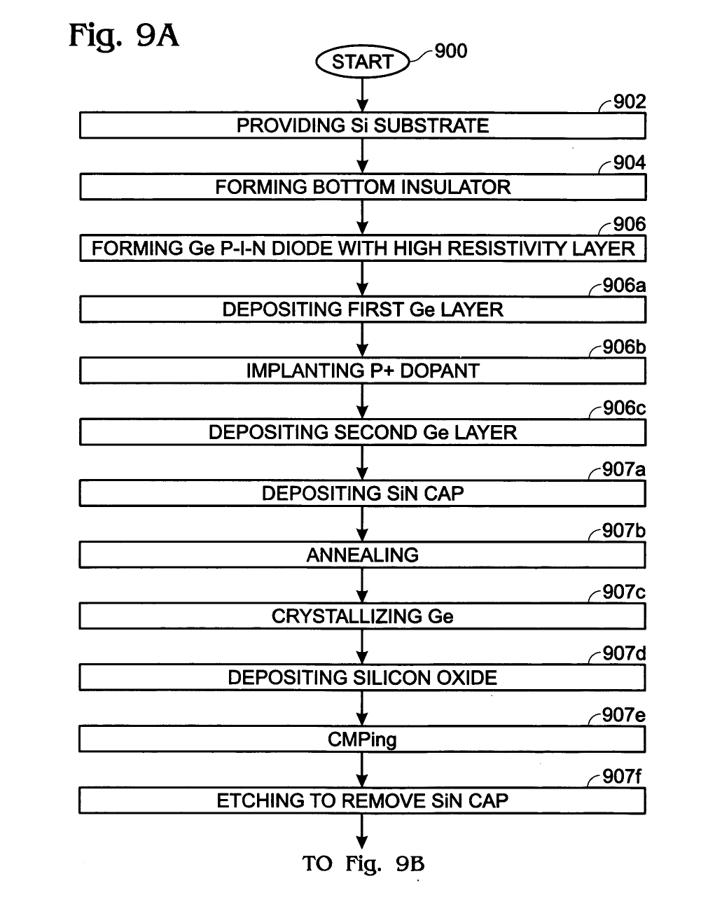

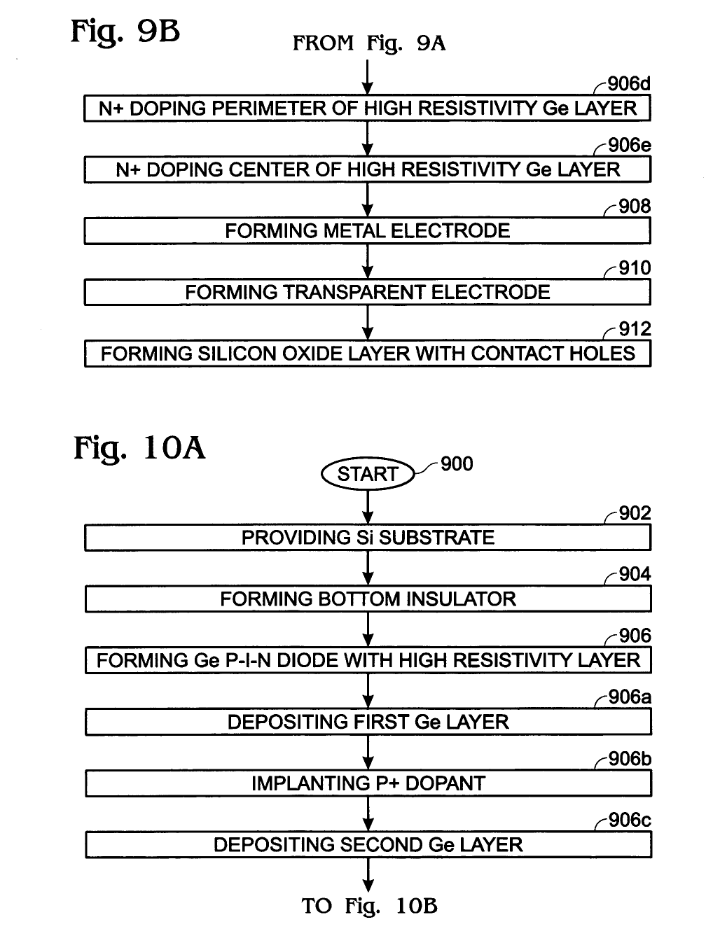

FIG. 9 is a flowchart illustrating a method for fabricating a LPE GOI photodiode with buried high resistivity Ge layer. Although the method is depicted as a sequence of numbered steps for clarity, the numbering does not necessarily dictate the order of the steps. It should be understood that some of these steps may be skipped, performed in parallel, or performed without the requirement of maintaining a strict order of sequence. The method starts at Step 900.

Step 902 provides a Si substrate. Step 904 forms a bottom insulator overlying the Si substrate with a Si seed access area. For example, the bottom insulator may be a silicon dioxide layer having a thickness in the range of about 10 to 40 nm. Step 906 forms a Ge P-I-N diode with an n +-doped (n+) mesa, a p+-doped (p+) Ge bottom insulator interface and mesa lateral interface. Step 906 also forms a high resistivity Ge layer interposed between the p+ Ge and n+ Ge. Step 908 forms a metal electrode overlying a region of the p+ Ge lateral interface. Step 910 forms a transparent electrode overlying the n+ Ge mesa. Step 912 forms a silicon oxide layer with contact holes overlying the p+ Ge mesa lateral interface, high resistivity Ge layer, and n+ Ge mesa. Following Step 912, conventional CMOS processes are used to form interconnects to other circuits and traces on the substrate.

In one aspect, forming the p+ Ge bottom insulator interface in Step 906 includes substeps. Step 906a deposits a first Ge layer overlying the bottom insulator and Si seed access area. Step 906b implants a p+ dopant into the first Ge layer. For example, Step 906a may deposit either amorphous or polycrystalline Ge, with a thickness in the range of about 20 to 50 nm. Step 906b implants p+ dopant into the first Ge layer with an energy in the range of about 30 KeV and 50 KeV, and a dosage in the range of about 2×10¹³ to 1×10¹⁵ per square centimeter (/cm²). In another aspect, Step 906c forms the high resistivity Ge layer by depositing a second Ge layer, or either amorphous or polycrystalline Ge, with a thickness in the range of about 0.3 and 3 micrometers (um), overlying the p+ Ge bottom insulator interface.

Step 907 describes the LPE process. Step 907a deposits a silicon nitride layer temporary cap overlying the high resistivity Ge layer. Step 907b anneals the Ge bottom interface and high resistivity Ge layer. Step 907c epitaxially crystallizes the Ge bottom interface and high resistivity Ge layer from the Si seed access area. For example, Step 907b may RTA using a temperature in the range of about 930 to 1000° C., for a duration in the range of about zero to 5 seconds.

In one aspect, Step 907d isotropically deposits a silicon oxide layer overlying the silicon nitride cap. Step 907e CMPs the silicon oxide, stopping at the silicon nitride cap. Step 907f etches to remove the silicon nitride cap, exposing the high resistivity Ge layer.

In another aspect, forming a p+ Ge mesa lateral interface (Step 906) includes a substep performed after Step 907f. Step 906d selectively p+-dopes the perimeter of the high resistivity Ge layer. Likewise, forming the n+ mesa includes a substep performed after Step 907f. Step 906e n+-dopes a center region of the high resistivity Ge layer using an energy in the range of about 10 KeV to 50 KeV, and a dosage in the range of about 2×10¹³ to 1×10¹⁵/cm⁻².

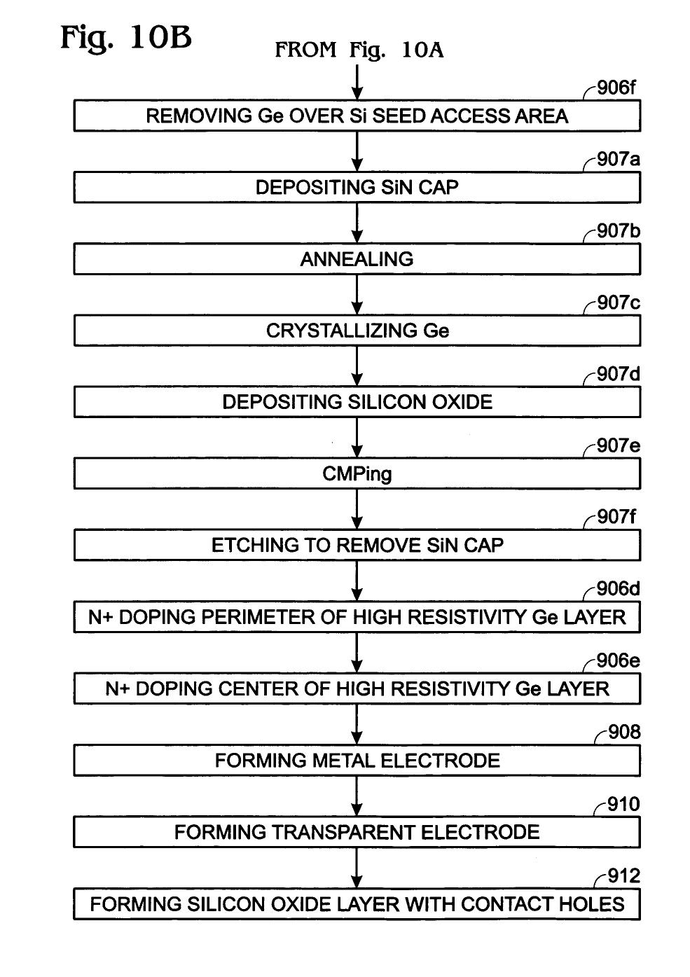

FIG. 10 is a flowchart depicting a variation in the fabrication method of FIG. 9. Steps 902 through 906c are as described above, and will not be repeated in the interest of brevity. In this aspect, Step 906f, following the formation of the high resistivity Ge layer (Step 906c), etches to remove regions of the p+ Ge bottom interface and the high resistivity Ge layer overlying the Si seed access area. Then, depositing the silicon nitride layer temporary cap overlying the high resistivity Ge layer in Step 907a includes forming a silicon nitride wall overlying the Si seed access area.

Step 907b through Step 906 are performed as described in the explanation of FIG. 9. In this aspect however, forming the metal electrode overlying the region of the p+ Ge mesa lateral interface (Step 908) includes forming the metal electrode overlying a region of p+ Ge mesa lateral interface adjacent the silicon nitride wall (see FIGS. 2 and 8).

A LPE GOI photodiode with a buried high resistivity Ge layer, and an associated fabrication process have been provided. Process details and particular materials have been mentioned in examples to illustrate the invention. However, the invention is not limited to merely these examples. Other variation and embodiments of the invention will occur to those skilled in the art.

We claim:

1. A method for fabricating a liquid phase epitaxial (LPE) Germanium-on-Insulator (GOI) photodiode with buried high resistivity Germanium (Ge) layer, the method comprising:
providing a silicon (Si) substrate;
forming a bottom insulator overlying the Si substrate with a Si seed access area;
forming a Ge P-I-N diode with an n +-doped (n+) mesa, a p+-doped (p+) Ge bottom insulator interface and mesa lateral interface, and a high resistivity Ge layer interposed between the p+ Ge and n+ Ge;
forming a metal electrode overlying a region of the p+ Ge lateral interface; and,
forming a transparent electrode overlying the n+ Ge mesa.

2. The method of claim 1 wherein forming the p+ Ge bottom insulator interface includes:
depositing a first Ge layer overlying the bottom insulator and Si seed access area; and,
implanting a p+ dopant into the first Ge layer.

3. The method of 2 wherein depositing the first Ge layer includes depositing a material selected from the group including amorphous and polycrystalline Ge, with a thickness in the range of about 20 to 50 nanometers (nm); and,
wherein implanting the p+ dopant in the first Ge layer includes:
implanting with an energy in the range of about 30 KeV and 50 KeV; and,
dosing in the range of about 2×10¹³ to 1×10¹⁵ per square centimeter (/cm²).

4. The method of claim 2 wherein forming the high resistivity Ge layer includes depositing a second Ge layer made from a material selected from the group consisting of amorphous and polycrystalline Ge, with a thickness in the range of about 0.3 and 3 micrometers (um), overlying the p+ Ge bottom insulator interface.

5. The method of claim 4 further comprising:
depositing a silicon nitride layer temporary cap overlying the high resistivity Ge layer;
annealing the Ge bottom interface and high resistivity Ge layer; and,
from the Si seed access area, epitaxially crystallizing the Ge bottom interface and high resistivity Ge layer.

6. The method of claim 5 wherein annealing includes rapid thermal annealing (RTA) using a temperature in the range of about 930 to 1000° C., for a duration in the range of about zero to 5 seconds.

7. The method of claim 5 further comprising:
isotropically depositing a silicon oxide layer overlying the silicon nitride cap;
chemical mechanically polishing (CMP) the silicon oxide, stopping at the silicon nitride cap; and,
etching to remove the silicon nitride cap, exposing the high resistivity Ge layer.

8. The method of claim 7 wherein forming a p+ Ge mesa lateral interface includes selectively p+-doping the perimeter of the high resistivity Ge layer.

9. The method of claim 8 wherein forming the n+ mesa includes n+-doping a center region of the high resistivity Ge layer using an energy in the range of about 10 KeV to 50 KeV, and a dosage in the range of about 2×10¹³ to 1×10¹⁵/cm⁻².

10. The method of claim 9 further comprising:
forming a silicon oxide layer with contact holes overlying the p+ Ge mesa lateral interface, high resistivity Ge layer, and n+ Ge mesa.

11. The method of claim 5 further comprising:
following the formation of the high resistivity Ge layer, etching to remove regions of the p+ Ge bottom interface and the high resistivity Ge layer overlying the Si seed access area; and,
wherein depositing the silicon nitride layer temporary cap overlying the high resistivity Ge layer includes forming a silicon nitride wall overlying the Si seed access area.

12. The method of claim 11 wherein forming the metal electrode overlying the region of the p+ Ge mesa lateral interface includes forming the metal electrode overlying a region of p+ Ge mesa lateral interface adjacent the silicon nitride wall.

13. The method of claim 1 wherein forming the bottom insulator includes forming a silicon dioxide layer having a thickness in the range of about 10 to 40 nm.

14. A liquid phase epitaxial (LPE) Germanium-on-Insulator (GOI) photodiode with a buried high resistivity Germanium (Ge) layer, the photodiode comprising:
a silicon (Si) substrate;
a bottom insulator overlying the Si substrate with a Si seed access area;
a Ge P-I-N diode with an n+-doped (n+) mesa, a p+-doped (p+) Ge bottom insulator interface and mesa lateral interface, and a high resistivity Ge layer interposed between the p+ Ge and n+ Ge;
a metal electrode overlying a region of the p+ Ge mesa lateral interface; and,
a transparent electrode overlying the n+ Ge mesa.

15. The photodiode of claim 14 wherein the p+ Ge bottom insulator interface has a thickness in the range of about 20 to 50 nanometers (nm).

16. The photodiode of claim 15 wherein the high resistivity Ge layer has a thickness in the range of about 0.3 and 3 micrometers (um).

17. The photodiode of claim 14 wherein the bottom insulator is silicon oxide, having a thickness in the range of about 10 to 40 nm.

18. The photodiode of claim 14 wherein the p+ Ge mesa lateral interface forms a perimeter around the high resistivity Ge layer.

19. The photodiode of claim 14 further comprising:
a silicon nitride insulator overlying the bottom insulator and adjacent the p+ Ge mesa lateral interface.

20. The photodiode of claim 19 wherein the silicon nitride insulator forms a wall overlying the Si seed access area.

21. The photodiode of claim 20 wherein the metal electrode overlies a region of p+ Ge mesa lateral interface adjacent the silicon nitride wall.
